(19) United States
(12) Patent Application Publication
(10) Pub. No.: US 2026/0020346 A1
(43) Pub. Date: Jan. 15, 2026

(54) ARRAY SUBSTRATE AND PREPARATION METHOD THEREFOR, DISPLAY PANEL, AND DISPLAY DEVICE

(71) Applicants: HEFEI XINSHENG OPTOELECTRONICS TECHNOLOGY CO., LTD., Anhui (CN); BOE TECHNOLOGY GROUP CO., LTD., Beijing (CN)

(72) Inventors: Hui AN, Beijing (CN); Binbin CAO, Beijing (CN); Chengzhi YE, Beijing (CN); Yanming LV, Beijing (CN)

(21) Appl. No.: 18/994,655

(22) PCT Filed: Dec. 23, 2022
(86) PCT No.: PCT/CN2022/141368

§ 371 Date: Jan. 15, 2025

(51) Int. Cl. H10D 86/40; G02F 1/1339; G02F 1/1362

(52) U.S. Cl. CPC H10D 86/441; G02F 1/1339; G02F 1/136209; G02F 1/136222; G02F 1/136286

(57) ABSTRACT

An array substrate has a display zone and a transition zone located on at least one side of the display zone. The array substrate includes a first base substrate, an insulating layer group, a first electrode layer and a conductive enhancement layer, wherein the insulating layer group is arranged on one side of the first base substrate, the insulating layer group is provided with a recess, and the recess is located in the transition zone; the first electrode layer is arranged on the side of the insulating layer group away from the first base substrate; and the conductive enhancement layer is arranged on the side of the first electrode layer away from the first base substrate, and the orthographic projection of the conductive enhancement layer on the first base substrate is located within the orthographic projection of the first electrode layer on the first base substrate.

### CROSS-REFERENCE TO RELATED APPLICATION

The present application is a National Stage of International Application No. PCT/CN2022/141368, filed on Dec. 23, 2022, the entire disclosure of which is incorporated herein by reference for all purposes.

### TECHNICAL FIELD

The present disclosure relates to the field of display technology, and specifically, to an array substrate and preparation method thereof, a display panel, and a display apparatus.

### BACKGROUND

In recent years, users have increasingly higher requirements for display quality, and display quality of existing display products cannot meet requirements of the users.

### SUMMARY

The purpose of the present disclosure is to provide an array substrate and preparation method thereof, a display panel, and a display apparatus.

According to one aspect of the present disclosure, there is provided an array substrate, having a display region and a transition region provided on at least one side of the display region, wherein the array substrate includes:
a first base substrate;
an insulating layer group, provided on a side of the first base substrate, wherein a recessed portion is provided on the insulating layer group, and the recessed portion is located in the transition region;
a first electrode layer, provided on a side of the insulating layer group away from the first base substrate; and
a conductive enhancement layer, provided on a side of the first electrode layer away from the first base substrate, wherein an orthographic projection of the conductive enhancement layer on the first base substrate is located within an orthographic projection of the first electrode layer on the first base substrate.

In an example embodiment of the present disclosure, a first via hole is further provided on the insulating layer group, the first via hole is located in the display region, and an area of an orthographic projection of the first via hole on the first base substrate is equal to or smaller than an area of an orthographic projection of the recessed portion on the first base substrate.

In an example embodiment of the present disclosure, a second via hole and a third via hole are provided on the first electrode layer, the second via hole is located in the display region, the third via hole is located in the transition region, the orthographic projection of the recessed portion on the first base substrate is located within an orthographic projection of the third via hole on the first base substrate, and the orthographic projection of the first via hole on the first base substrate is located within an orthographic projection of the second via hole on the first base substrate.

In an example embodiment of the present disclosure, an area of the orthographic projection of the third via hole on the first base substrate is greater than or equal to an area of the orthographic projection of the second via hole on the first base substrate.

In an example embodiment of the present disclosure, a spacing between an edge line of the orthographic projection of the recessed portion on the first base substrate and an edge line of the orthographic projection of the third via hole on the first base substrate is greater than or equal to a spacing between an edge line of the orthographic projection of the first via hole on the first base substrate and an edge line of the orthographic projection of the second via hole on the first base substrate.

In an example embodiment of the present disclosure, the conductive enhancement layer includes:
a first conductive strip, extending along a first direction;
a second conductive strip, extending along a second direction, wherein the second direction intersects with the first direction, and the first direction and the second direction are parallel to a side of the first base substrate close to the insulating layer group.

In an example embodiment of the present disclosure, a spacing between an edge line of the orthogonal projection of the third via hole on the first base substrate and an edge line of an orthogonal projection of an adjacent first conductive strip on the first base substrate is greater than or equal to a spacing between an edge line of the orthogonal projection of the second via hole on the first base substrate and an edge line of an orthogonal projection of an adjacent first conductive strip on the first base substrate; and a spacing between the edge line of the orthogonal projection of the third via hole on the first base substrate and an edge line of an orthogonal projection of an adjacent second conductive strip on the first base substrate is greater than or equal to a spacing between an edge line of the orthogonal projection of the second via hole on the first base substrate and an edge line of an orthogonal projection of an adjacent second conductive strip on the first base substrate.

In an example embodiment of the present disclosure, the array substrate further includes:
a switch layer group, provided between the first base substrate and the insulating layer group, the switch layer group including:
a plurality of switch units, provided in an array;
a plurality of gate lines, extending along the first direction, wherein each of the gate lines is located between two adjacent switch units, an orthographic projection of the first conductive strip on the first base substrate at least partially overlaps with an orthographic projection of the gate line on the first base substrate;
a plurality of data lines, extending along the second direction, wherein each of the data lines is located between two adjacent switch units, an orthographic projection of the second conductive strip on the first base substrate at least partially overlaps with an orthographic projection of the data line on the first base substrate, and the plurality of gate lines and the plurality of data lines intersect to form a plurality of pixel regions.

In an example embodiment of the present disclosure, at least two recessed portions and at least two third via holes are provided in one of the pixel regions in the transition region; one first via hole and one second via hole are provided in one of the pixel regions in the display region.

In an example embodiment of the present disclosure, the recessed portion and the first via hole located in a row of pixel regions arranged along the first direction are located in an identical region in a corresponding pixel region.

In an example embodiment of the present disclosure, only one row of pixel regions arranged along the first direction is arranged in the transition region on a side of the second direction of the display region, and only one column of pixel regions arranged along the second direction is arranged in the transition region on a side of the first direction of the display region.

In an example embodiment of the present disclosure, in the transition region, the switch unit does not include a drain and a drain connection lead, and the orthographic projection of the recessed portion on the first base substrate does not overlap with the switch unit.

In an example embodiment of the present disclosure, a distance between a lowest point of the recessed portion and the first base substrate is smaller than a distance between a lowest point of the first via hole and the first base substrate.

In an example embodiment of the present disclosure, the conductive enhancement layer further includes:
a plurality of lead strips, wherein an end of the lead strip is connected to the second conductive strip, and the lead strip extends along the first direction toward a side away from the display region.

In an example embodiment of the present disclosure, an orthographic projection of the lead strip on the first base substrate does not overlap with the orthographic projection of the gate line on the first base substrate.

In an example embodiment of the present disclosure, two data lines are provided between orthographic projections of two adjacent second conductive strips on the first base substrate.

In an example embodiment of the present disclosure, the conductive enhancement layer further includes:
a collection connection strip, connected to an end of the lead strip away from the second conductive strip, the collection connection strip extending along the second direction.

In an example embodiment of the present disclosure, the insulating layer group includes:
a first insulating layer, provided on a side of the first base substrate, wherein a fifth via hole is provided on the first insulating layer, the fifth via hole is located in the display region and is connected to the switch unit;
an organic insulating layer, provided on a side of the first insulating layer away from the first base substrate, wherein a sixth via hole and a seventh via hole are provided on the organic insulating layer, the sixth via hole is the recessed portion, and the seventh via hole is connected with the fifth via hole to form the first via hole.

In an example embodiment of the present disclosure, the array substrate further includes:
a second insulating layer, provided on a side of the conductive enhancement layer away from the first base substrate, wherein a fourth via hole is provided on the second insulating layer, an orthographic projection of the seventh via hole on the first base substrate covers and is larger than an orthographic projection of the fourth via hole on the first base substrate, the second insulating layer covers a hole sidewall of the seventh via hole, and covers a part of the first insulating layer exposed in the seventh via hole, such that the second insulating layer forms a step portion in the seventh via hole;
a second electrode layer, provided on a side of the second insulating layer away from the first base substrate, wherein the second electrode layer includes a plurality of second electrodes, the second electrode includes a main body portion and a connecting portion connected to each other, the connecting portion is connected to the switch unit through the fourth via hole and the fifth via hole, and the main body portion is located on a side of the step portion away from the first base substrate.

In an example embodiment of the present disclosure, the array substrate further includes:
a first spacer, provided on a side of the second electrode layer away from the first base substrate and located between two adjacent switch units;
the orthographic projection of the first conductive strip on the first base substrate is provided as a curve, and the first conductive strip is bent toward a side away from the first spacer at a position adjacent to the first spacer.

In an example embodiment of the present disclosure, the orthographic projection of the first conductive strip on the first base substrate does not overlap with an orthographic projection of the first spacer on the first base substrate.

In an example embodiment of the present disclosure, the first conductive strip includes a first straight portion and a first curved portion, an orthographic projection of the first straight portion on the first base substrate is located within the orthographic projection of the gate line on the first base substrate, and an orthographic projection of the first curved portion on the first base substrate at least partially does not overlap with the orthographic projection of the gate line on the first base substrate.

In an example embodiment of the present disclosure, the array substrate further includes a peripheral region, the peripheral region is provided on a side of the transition region away from the display region, the peripheral region is provided with a plurality of peripheral leads, in a third direction, a height of the insulating layer group in the peripheral region is higher than a height of the insulating layer group in the display region, and the third direction is perpendicular to a side of the first base substrate close to the insulating layer group.

In an example embodiment of the present disclosure, a distance between an edge line of a side of the recessed portion close to the display region and the display region is greater than a distance between an edge line of a side of the recessed portion close to the peripheral region and the peripheral region.

In an example embodiment of the present disclosure, the orthographic projection of the conductive enhancement layer on the first base substrate does not overlap with an orthographic projection of the recessed portion on the first base substrate.

In an example embodiment of the present disclosure, the array substrate further includes:

a protective layer, provided on a side of the conductive enhancement layer away from the first base substrate.

According to another aspect of the present disclosure, there is provided a method for preparing an array substrate, including:
providing a first base substrate, wherein the first base substrate has a display region and a transition region provided on at least one side of the display region, an insulating layer group is formed on a side of the first base substrate, a recessed portion is formed on the insulating layer group, and the recessed portion is located in the transition region;
forming a first electrode material layer and a conductive enhancement material layer successively on a side of the insulating layer group away from the first base substrate;
forming a mask layer on a side of the conductive enhancement material layer away from the first base substrate, wherein a part of the mask layer is formed in the recessed portion, and a thickness of the mask layer in the display region is consistent; and
using the mask layer as a mask, patterning the first electrode material layer to form a first electrode layer, and patterning the conductive enhancement material layer to form a conductive enhancement layer.

In an example embodiment of the present disclosure, while forming the recessed portion, a first via hole is formed on the insulating layer group, the first via hole is located in the display region, and an area of an orthographic projection of the first via hole on the first base substrate is equal to or smaller than an area of an orthographic projection of the recessed portion on the first base substrate.

In an example embodiment of the present disclosure, using the mask layer as a mask, patterning the first electrode material layer to form a first electrode layer, and patterning the conductive enhancement material layer to form a conductive enhancement layer includes:
performing a half-mask process on the mask layer to form a mask pattern, wherein the mask pattern includes a first portion and a second portion, a thickness of the first portion is greater than a thickness of the second portion, a ninth via hole is formed on the second portion, a part of the ninth via hole is arranged opposite to the first via hole, and another part of the ninth via hole is arranged opposite to the recessed portion;
etching and removing a part of the conductive enhancement material layer opposite to the ninth via hole;
ashing the mask pattern to remove the second portion, such that the conductive enhancement material layer covered by the second portion is exposed;
etching and removing a part of the first electrode material layer opposite to the ninth via hole, to form the first electrode layer; and
patterning a remaining conductive enhancement material layer to form the conductive enhancement layer.

According to yet another aspect of the present disclosure, there is provided a display panel, including:
any of the array substrates described above; and
a color film substrate, provided opposite to the array substrate, wherein the color film substrate includes a black matrix, and an orthographic projection of the conductive enhancement layer on the first base substrate is located within an orthographic projection of the black matrix on the first base substrate.

According to another aspect of the present disclosure, there is provided a display panel, including:
any of the array substrates described above; and
a color film substrate, provided opposite to the array substrate, wherein the color film substrate includes a black matrix, an orthographic projection of the conductive enhancement layer on the first base substrate is located within an orthographic projection of the black matrix on the first base substrate, and an edge line of a side of the black matrix close to the first conductive strip is provided as a curve adapted to the first conductive strip.

According to yet another aspect of the present disclosure, there is provided a display apparatus, including the display panels described above.

It should be understood that the above general description and the detailed description below are only exemplary and explanatory, and cannot limit the present disclosure.

### BRIEF DESCRIPTION OF THE DRAWINGS

The drawings herein are incorporated into the specification and constitute a part of the specification, showing embodiments consistent with the present disclosure, and are used together with the specification to explain the principles of the present disclosure. The drawings described below are only some embodiments of the present disclosure, and for ordinary technicians in the field, other drawings can also be obtained based on these drawings without creative work.

FIGS. 1 to 7 are structural schematic diagrams of each step of forming a conductive enhancement layer when the mask layer is thick.

FIG. 8 is a structural schematic diagram of the first example embodiment of the array substrate of the present disclosure.

FIG. 9 is a structural schematic diagram of an example embodiment of a gate layer in the array substrate of the present disclosure.

FIG. 10 is a structural schematic diagram of forming an active layer based on FIG. 9.

FIG. 11 is a structural schematic diagram of forming a connecting conductor layer based on FIG. 10.

FIG. 12 is a structural schematic diagram of forming an insulating layer group, a first electrode layer and a conductive enhancement layer based on FIG. 11.

FIG. 13 is a schematic diagram of the size relationship between the recessed portion of the transition region and the third via hole, the conductive enhancement layer.

FIG. 14 is a schematic diagram of the size relationship between the first via hole in the display region and the second via hole, the conductive enhancement layer.

FIG. 15 is a structural schematic diagram of the conductive enhancement layer.

FIG. 16 is a structural schematic diagram of the second example embodiment of the array substrate of the present disclosure.

FIG. 17 is a structural schematic diagram of the third example embodiment of the array substrate of the present disclosure.

FIG. 18 is a structural schematic diagram of the top view of the fourth example embodiment of the array substrate of the present disclosure.

FIG. 19 is a structural schematic diagram of the top view of the fifth example embodiment of the array substrate of the present disclosure.

FIG. 20 is a schematic flow diagram of an example embodiment of the method for preparing an array substrate of the present disclosure.

FIGS. 21-27 are structural schematic diagrams of each step of the method for preparing an array substrate of the present disclosure.

FIG. 28 is a structural schematic diagram of an example embodiment of the display panel of the present disclosure.

### EXPLANATION OF REFERENCE NUMERALS

100, array substrate; 200, color film substrate;
1, first base substrate;
2, switch layer group; 21, switch unit; 22, gate layer; 221, gate line; 222, gate; 223, peripheral lead; 23, gate insulation layer; 24, active layer; 241, channel portion; 242, source; 243, drain; 25, connecting conductor layer; 251, source connection lead; 252, drain connection lead; 253, data line; 26, pixel region;
3, insulation layer group; 31, first insulation layer; 311, fifth via hole; 32, organic insulation layer; 321, sixth via hole; 322, seventh via hole; 323, cavity; 33, recessed portion; 34, first via hole;
40, first electrode material layer; 4, first electrode layer; 41, second via hole; 42, third via hole;
50, conductive enhancement material layer; 5, conductive enhancement layer;
51, first conductive strip; 511, first straight portion; 512, first curved portion; 52, second conductive strip; 53, lead strip; 54, collection connection strip;
6, second insulating layer; 61, fourth via hole; 62, step portion;
7, second electrode layer; 71, second electrode; 711, main body; 712, connection portion;
81, first spacer; 82, second spacer;
9, mask layer; 91, mask pattern; 911, first portion; 912, second portion; 913,
ninth via hole;
201, second base substrate; 202, black matrix; 203, filter portion;
X, first direction; Y, second direction; Z, third direction;
AA, display region; DUM, transition region; WW, peripheral region.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and the concepts of the example embodiments will be fully conveyed to those skilled in the art. The same reference numerals in the drawings represent the same or similar structures, and their detailed descriptions will be omitted. In addition, the drawings are only schematic illustrations of the present disclosure and are not necessarily drawn to scale.

Although relative terms such as “upper” and “lower” are used in this specification to describe the relative relationship of one component of the icon to another component, these terms are used in this specification only for convenience, such as according to the direction of the examples described in the drawings. It is understood that if the device of the icon is flipped so that it is upside down, the component described as “upper” will become the component “lower”. When a structure is “on” another structure, it may mean that a structure is formed integrally on the other structure, or that a structure is “directly” set on the other structure, or that a structure is “indirectly” set on the other structure through another structure.

The terms “one”, “an”, “the”, “said” and “at least one” are used to indicate the existence of one or more elements/components/etc.; the terms “including” and “having” are used to indicate an open-ended inclusion and mean that there may be other elements/components/etc. in addition to the listed elements/components/etc.; the terms “first”, “second” and “third” are used only as markers and are not restriction of the quantity on the objects.

In this application, unless otherwise clearly specified and defined, the term “connection” should be understood in a broad sense. For example, “connection” can be a fixed connection, a detachable connection, or an integral connection; it can be directly connected or indirectly connected through an intermediate medium. “And/or” is only a description of the association relationship of the associated objects, indicating that there can be three relationships. For example, A and/or B can represent: A exists alone, A and B exist at the same time, and B exists alone. In addition, the character “/” in this description generally indicates that the associated objects before and after “/” are in an “or” relationship.

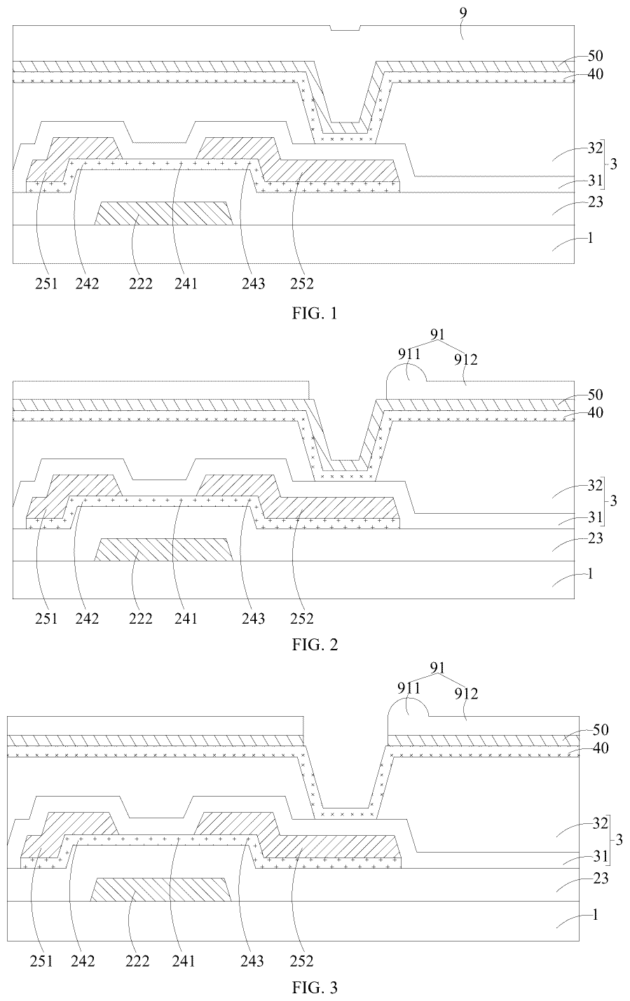

At present, the display brightness of the display panel is uneven, mainly because that the brightness of the edge area of the display region AA is low. Referring to FIGS. 1 to 8, the inventors found that the main reason for the defect is excessive residues of the conductive enhancement layer 5 in the edge area of the display region AA, and the conductive enhancement layer 5 will affect the transmittance, thereby making the transmittance of the edge area of the display region AA low. The reason of excessive residues of the conductive enhancement layer 5 in the display region AA is that a large area of peripheral leads 223 is provided in the peripheral region WW, resulting in that the height of the peripheral region WW is higher than the height of the display region AA and the height of the transition region DUM, and a mask layer 9 is formed by a coating or printing process on the side of the conductive enhancement material layer 50 away from the first base substrate 1, and since the material of the mask layer 9 has certain fluidity, it will flow from the higher region to the lower region, therefore, the material of the mask layer 9 will flow from the peripheral region WW to the transition region DUM and the display region AA, resulting in a thick mask layer 9 in the edge area of the display region AA close to the transition region DUM, as a result, when the conductive enhancement material layer 50 is etched to form the conductive enhancement layer 5, there is more residue of the mask layer 9 in the edge area of the display region AA close to the transition region DUM, that is, the shielding area of the mask layer 9 on the conductive enhancement material layer 50 is large, and finally it results in a large area of the formed conductive enhancement layer 5, resulting in a low light transmittance and low brightness of the edge area of the display region AA.

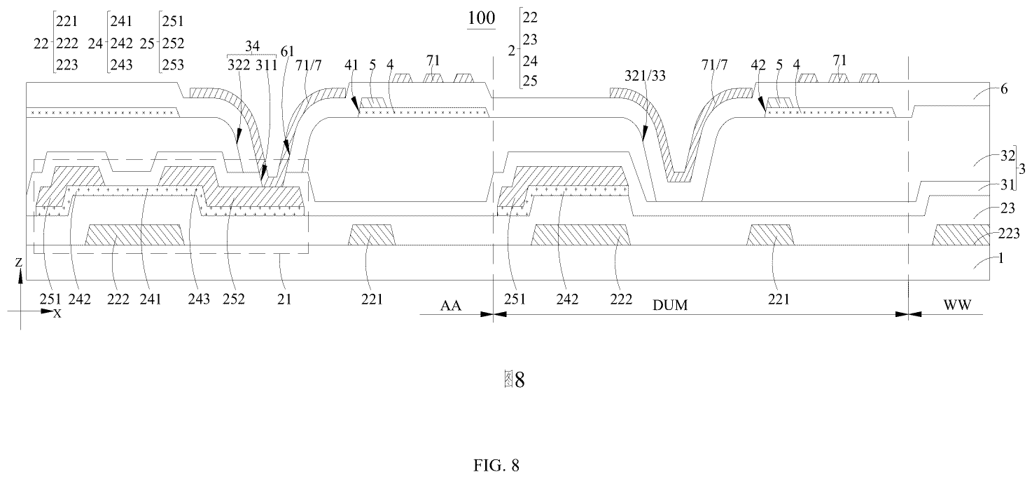

The example embodiment of the present disclosure provides an array substrate 100, as shown in FIGS. 8 to 19, the array substrate 100 has a display region AA and a transition region DUM disposed on at least one side of the display region AA, and the array substrate 100 may include a first base substrate 1, an insulating layer group 3, a first electrode layer 4, and a conductive enhancement layer 5; the insulating layer group 3 is disposed on one side of the first base substrate 1, and a recessed portion 33 is disposed on the insulating layer group 3, and the recessed portion 33 is located in the transition region DUM; the first electrode layer 4 is disposed on the side of the insulating layer group 3 away from the first base substrate 1; the conductive enhancement layer 5 is disposed on the side of the first electrode layer 4 away from the first base substrate 1, and the orthographic projection of the conductive enhancement layer 5 on the first base substrate 1 is located within the orthographic projection of the first electrode layer 4 on the first base substrate 1.

The array substrate 100 and its preparation method disclosed in the present disclosure, on the one hand, a recessed portion 33 is provided on the insulating layer group 3, and the recessed portion 33 is located in the transition region DUM; in this way, when the first electrode layer 4 and the conductive enhancement layer 5 are formed, the mask layer 9 formed on the side of the conductive enhancement material layer 50 away from the first base substrate 1 will flow into the recessed portion 33 of the transition region DUM when flowing from the peripheral region WW to the display region AA, so that the thickness of the mask layer 9 in the display region AA is uniform, and when the conductive enhancement material layer 50 is etched to form the conductive enhancement layer 5, the shielding area of the mask layer 9 at various locations in the display region AA on the conductive enhancement material layer 50 is substantially the same, so that the area of the formed conductive enhancement layer 5 is substantially consistent, and the brightness at various locations in the display region AA is also substantially consistent. On the other hand, the conductive enhancement layer 5 can reduce the resistance of the first electrode layer 4, thereby reducing the power consumption of the array substrate 100, and reducing the heat generation of the array substrate 100.

It should be noted that, in this specification, the first direction X and the second direction Y are parallel to the side of the first base substrate 1 close to the insulating layer group 3, and the first direction X intersects with the second direction Y. For example, the first direction X may be perpendicular to the second direction Y. The third direction Z is perpendicular to the side of the first base substrate 1 close to the insulating layer group 3, that is, the third direction Z is perpendicular to both the first direction X and the second direction Y.

The array substrate 100 may include a display region AA, a transition region DUM and a peripheral region WW. The transition region DUM is provided on at least one side of the display region AA. For example, when the display region AA is provided in a rectangular shape, the transition region DUM may be provided around the display region AA. The peripheral region WW is provided on the side of the transition region DUM away from the display region AA, and the display region AA, the transition region DUM and the peripheral region WW are connected successively.

In this example embodiment, the material of the first base substrate 1 may include an inorganic material. For example, the inorganic material may be glass, quartz or metal or the like. The material of the first base substrate 1 may also include an organic material, for example, the organic material may be a resin material such as polyimide, polycarbonate, polyacrylate, polyetherimide, polyethersulfone, polyethylene terephthalate and polyethylene naphthalate. The base substrate may be formed by a plurality of material layers, for example, the base substrate may include a plurality of second base substrates 201, and the material of the second base substrate 201 may be any of the above materials. The base substrate may also be set as a single layer, which may be any of the above materials.

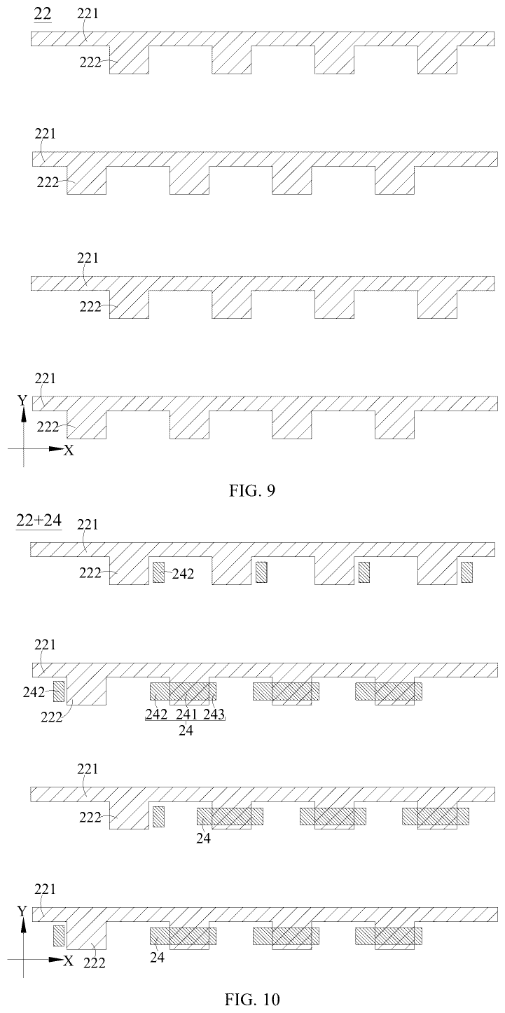

In this example embodiment, as shown in FIGS. 8 and 9, a switch layer group 2 may be provided on a side of the first base substrate 1, and the switch layer group 2 may include a gate layer 22, a gate insulating layer 23, an active layer 24 and a connecting conductor layer 25.

Specifically, a gate layer 22 may be provided on a side of the first base substrate 1, and the gate layer 22 may include a plurality of gates 222 and a plurality of gate lines 221. The gate line 221 extends along the first direction X, and a plurality of gates 222 are connected to one gate line 221; a portion of the gate line 221 may also be used as the gate 222.

In this example embodiment, as shown in FIG. 8, a gate insulating layer 23 is provided on the side of the gate layer 22 away from the first base substrate 1.

As shown in FIGS. 8 and 10, an active layer 24 is provided on the side of the gate insulating layer 23 away from the first base substrate 1, and the active layer 24 may include a channel portion 241, a source 242, and a drain 243. The channel portion 241 is provided on the side of the gate 222 away from the first base substrate 1. In the case where a portion of the gate line 221 is used as the gate 222, a portion of the gate line 221 opposite to the channel portion 241 is used as the gate 222. Two portions are provided at opposite ends of the channel portion 241, one portion of which may be the source 242, and the other portion may be the drain 243.

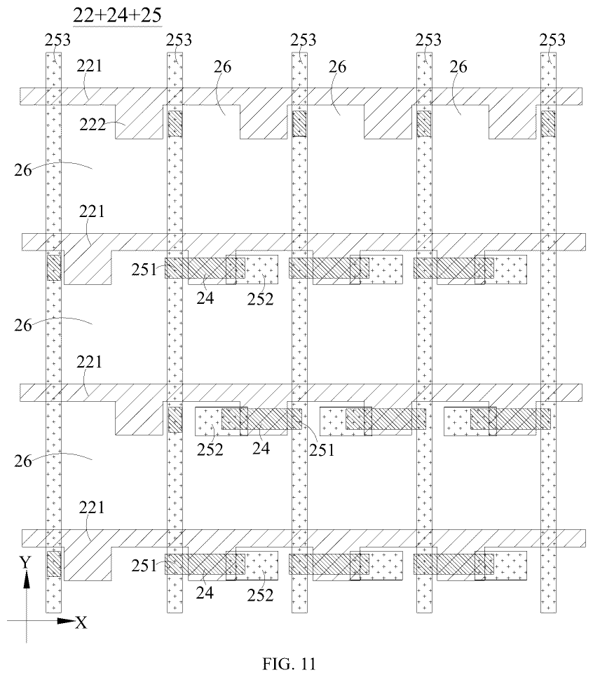

In this example embodiment, as shown in FIGS. 8 and 11, a connecting conductor layer 25 is provided on the side of the active layer 24 away from the first base substrate 1, and the connecting conductor layer 25 may include a plurality of source connection leads 251, a plurality of drain connection leads 252 and a plurality of data lines 253. The data line 253 extends along the second direction Y. Therefore, the data line 253 and the gate line 221 will inevitably intersect, and the plurality of data lines 253 and the plurality of gate lines 221 intersect to form a plurality of pixel regions 26.

It should be noted that, the source 242 and the drain 243 are not limited to the above description. For example, a portion of the drain connection lead 252 overlapping with one end of the channel portion 241 may also be the drain 243, and a portion of the source connection lead 251 overlapping with the other end of the channel portion 241 may also be the source 242.

Only one row of pixel regions 26 arranged along the first direction X is provided in the transition region DUM on one side of the second direction Y of the display region AA, and only one column of pixel regions 26 arranged along the second direction Y is provided in the transition region DUM on one side of the first direction X of the display region AA. For example, a circle of pixel regions 26 may be provided around the periphery of the display region AA, that is, the number of rows and columns of pixel regions 26 in the transition region DUM is reduced.

Since no recessed portion 33 is provided on the insulating layer group 3 on the transition region DUM, the transition region DUM approaches a relatively horizontal plane; however, a first via hole 34 is provided on the insulating layer group 3 of the display region AA, so that the average height of the display region AA is lower than the average height of the transition region DUM, so that the material of the mask layer 9 of the transition region DUM also tends to flow toward the display region AA. The number of rows and columns of the pixel region 26 in the transition region DUM is reduced, so that the area of the transition region DUM is reduced, and the total amount of the material of the mask layer 9 in the transition region DUM is reduced, which can alleviate the amount of the material of the mask layer 9 flowing to the display region AA, avoid the thickness of the mask layer 9 in the edge area of the display region AA being thick, and avoid the low transmittance and low brightness caused by the large amount of residue of the conductive enhancement layer 5.

One end of the source connection lead 251 is connected to the data line 253, and the other end is connected to the source 242; it can also be that a part of the data line 253 is used as the source connection lead 251. One end of the drain connection lead 252 is connected to the drain 243.

The gate 222, the channel portion 241, the source 242 and the drain 243 or the like form a switch unit 21, and the switch unit 21 is a thin film transistor.

It should be noted that, the thin film transistor described in this specification is a bottom gate thin film transistor. In other example embodiments of the present disclosure, the thin film transistor can also be a top gate type or a double gate type, and its specific structure is not repeated here. Moreover, in the case of using thin film transistors with opposite polarities or when the current direction changes during the circuit operation, the functions of the “source 242” and the “drain 243” are sometimes interchanged. Therefore, in this specification, the “source 242” and the “drain 243” can be interchanged.

The above-mentioned switch unit 21 is a specific structure of the switch unit 21 of the display region AA. In some example embodiments of the present disclosure, a switch unit 21 can be provided in the transition region DUM, and the specific structure of the switch unit 21 can be the same as the specific structure of the switch unit 21 of the display region AA; in other example embodiments of the present disclosure, since the source connection lead 251 is a part of the data line 253, and in order to maintain the consistency of electrical performance, only a part of the source connection lead 251 close to the data line 253 can be provided, and the source connection lead 251 and the active layer 24 are formed by the same patterning process, therefore, referring to FIG. 8, an active layer 24 connected to the source connection lead 251 and located on the side of the source connection lead 251 close to the first base substrate 1 may also be provided, that is, the drain connection lead 252 and another part of the active layer 24 connected to the drain connection lead 252 are not provided; that is, the drain connection lead 252 and the drain 243 connected to the drain connection lead 252 are not provided, so that the depth of the via hole can be deeper, that is, the distance between the lowest point of the recessed portion 33 and the first base substrate 1 is smaller than the distance between the lowest point of the first via hole 34 and the first base substrate 1, and more materials of the mask layer 9 can be accommodated. In the case where the source connection lead 251 and the active layer 24 are not formed by the same patterning process, the active layer 24 connected to the source connection lead 251 and located on the side of the source connection lead 251 close to the first base substrate 1 may also be not provided, that is, the active layer 24 is not provided in the transition region DUM. In some further example embodiments of the present disclosure, when the source connection lead 251 is not a part of the data line 253, the source connection lead 251 may also not be provided, and only the data line 253 is provided.

The switch unit 21 of the transition region DUM may be provided according to the product structure requirements and process requirements. The switch unit 21 of the transition region DUM does not need to be connected to the second electrode 71, and does not need to provide voltage to the second electrode 71. Therefore, the structure of the switch unit 21 may be incomplete, and may only include one component, two components, or more components of the above-mentioned complete switch unit 21.

As shown in FIG. 8, a plurality of peripheral leads 223 are provided in the peripheral region WW, and both the data line 253 and the gate line 221 are connected to the peripheral lead 223. The peripheral lead 223 may be provided in the same layer and same material as the gate line 221, or may also be provided in the same layer and same material as the data line 253, or it may also be that two layers of peripheral leads 223 are provided. A data signal is input to the data line 253 through the peripheral lead 223, a control signal is input to the gate line 221 through the peripheral lead 223, and some feedback signals are output through the peripheral lead 223. Moreover, the number of peripheral leads 223 is large, which almost covers the entire peripheral region WW, resulting in that after the first electrode material layer 40 and the conductive enhancement material layer 50 are formed, the height of the peripheral region WW in the third direction Z is higher than the height of the display region AA in the third direction Z. When the first electrode material layer 40 and the conductive enhancement material layer 50 are subsequently etched, after the mask layer 9 is formed on the side of the conductive enhancement material layer 50 away from the first base substrate 1, the mask layer 9 has certain fluidity, and the material of the mask layer 9 will flow from the peripheral region WW to the transition region DUM and the display region AA, resulting in a thicker mask layer 9 in the edge area of the display region AA close to the transition region DUM, and then when the conductive enhancement material layer 50 is etched to form the conductive enhancement layer 5, there is more residue of the mask layer 9 in the edge area of the display region AA close to the transition region DUM, that is, the shielding area of the mask layer 9 on the conductive enhancement material layer 50 is large, and finally it results in a large area of the formed conductive enhancement layer 5, resulting in a low light transmittance and low brightness of the edge area of the display region AA.

In this example embodiment, as shown in FIG. 8, an insulating layer group 3 is provided on the side of the connecting conductor layer 25 away from the first base substrate 1. The insulating layer group 3 may include a first insulating layer 31 and an organic insulating layer 32. The first insulating layer 31 is provided on the side of the connecting conductor layer 25 away from the first base substrate 1. A fifth via hole 311 is provided on the first insulating layer 31. The fifth via hole 311 is located in the display region AA, and the fifth via hole 311 is connected to the drain connection lead 252, so that the drain connection lead 252 is exposed. The material of the first insulating layer 31 may be an inorganic material, for example, silicon nitride, silicon oxide, etc. The thickness of the first insulating layer 31 is greater than or equal to 100 nm and less than or equal to 500 nm.

As shown in FIG. 8, the organic insulating layer 32 is provided on the side of the first insulating layer 31 away from the first base substrate 1. The material of the organic insulating layer 32 may be an organic material, for example, polyimide, polycarbonate, polyacrylate, etc. The thickness of the organic insulating layer 32 is greater than or equal to 1.5 μm and less than or equal to 5 μm.

The organic insulating layer 32 can play a flattening role, which provides a relatively flat base for the subsequently formed first electrode layer 4, facilitates the forming of the first electrode layer 4, thereby improving the uniformity of the first electrode layer 4; in addition, the organic insulating layer 32 increases the distance between the first electrode layer 4 and the data line 253 in the third direction Z, weakens the mutual influence, and greatly reduces the parasitic capacitance, which is more conducive to the driving of the driving chip; after the distance between the first electrode layer 4 and the data line 253 in the third direction Z increases, the distance between the first electrode layer 4 and the data line 253 in other directions (for example, in the first direction X and the second direction Y) can be shortened, so that the width of the black matrix 202 of the color film substrate 200 can also be made smaller, thereby improving the aperture ratio of the product.

The sixth via hole 321 and the seventh via hole 322 are arranged on the organic insulating layer 32, and the sixth via hole 321 is located in the transition region DUM, and the sixth via hole 321 forms the recessed portion 33 of the insulating layer group 3. The seventh via hole 322 is located in the display region AA, and the seventh via hole 322 is connected with the fifth via hole 311 to form the first via hole 34 of the insulating layer group 3, so that the drain connection lead 252 is exposed.

In some other example embodiments of the present disclosure, an eighth via hole can also be set on the first insulating layer 31, and the eighth via hole is located in the transition region DUM. The sixth via hole 321 can be connected with the eighth via hole to form the recessed portion 33 of the insulating layer group 3.

The area of the orthographic projection of the first via hole 34 on the first base substrate 1 is equal to or less than the area of the orthographic projection of the recessed portion 33 on the first base substrate 1, that is, the area of the recessed portion 33 located in the transition region DUM is set large, so that the recessed portion 33 can accommodate more photoresist material, and avoid the thickness of the mask layer 9 in the edge area of the display region AA close to the transition region DUM in the third direction Z being large, resulting in the residue of the conductive enhancement layer 5, thereby affecting the aperture ratio of the array substrate 100 and the display effect of the display panel.

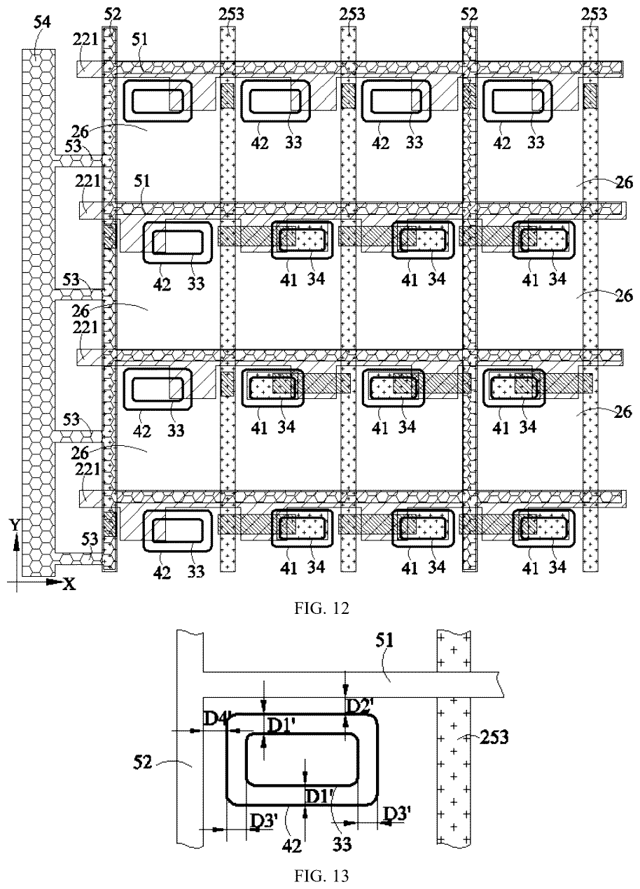

In this example embodiment, referring to FIGS. 1 and 12, since both the insulating layer group 3 and the first electrode layer 4 are transparent, FIG. 12 does not show the insulating layer group 3 and the first electrode layer 4, but shows the second via hole 41 and the third via hole 42 on the first electrode layer 4, the recessed portion 33 and the first via hole 34 on the insulating layer group 3; the first electrode layer 4 is provided on the side of the insulating layer group 3 away from the first base substrate 1, and the second via hole 41 and the third via hole 42 are provided on the first electrode layer 4, the second via hole 41 is located in the display region AA, and the second via hole 41 is connected to the first via hole 34; the orthographic projection of the first via hole 34 on the first base substrate 1 is located within the orthographic projection of the second via hole 41 on the first base substrate 1, for example, the orthographic projection of the second via hole 41 on the first base substrate 1 covers the orthographic projection of the first via hole 34 on the first base substrate 1, and the area of the orthographic projection of the second via hole 41 on the first base substrate 1 is larger than the area of the orthographic projection of the first via hole 34 on the first base substrate 1.

The third via hole 42 is located in the transition region DUM, the third via hole 42 is connected to the recessed portion 33, and the orthographic projection of the recessed portion 33 on the first base substrate 1 is located within the orthographic projection of the third via hole 42 on the first base substrate 1. For example, the orthographic projection of the third via hole 42 on the first base substrate 1 covers and is larger than the orthographic projection of the recessed portion 33 on the first base substrate 1.

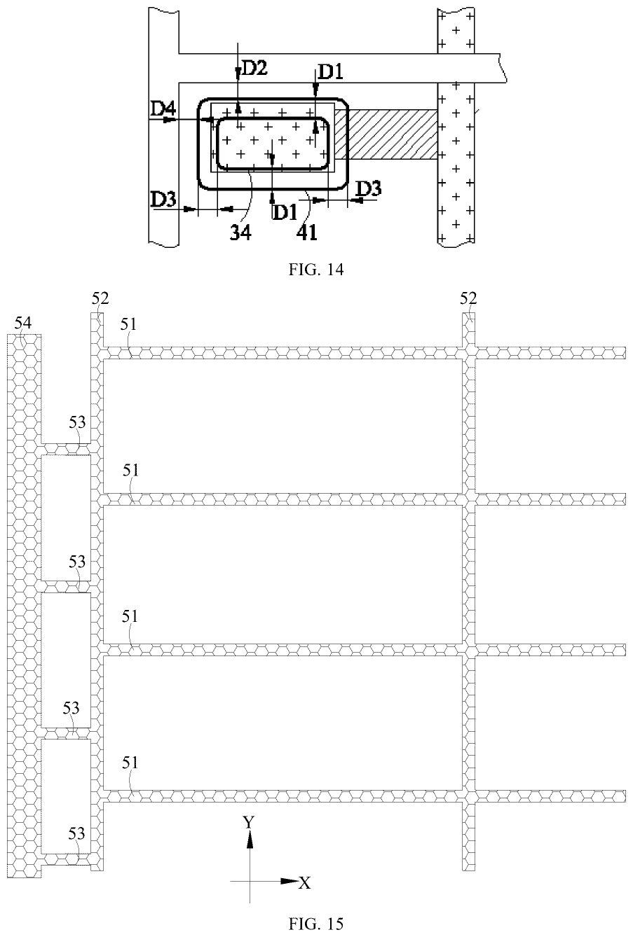

Moreover, referring to FIGS. 13 and 14, since the size relationship shown in the drawings is not much related to the gate layer 22, the gate layer 22 is omitted in the drawings, and the spacing (D1′ and D3′) between the edge line of the orthographic projection of the recessed portion 33 on the first base substrate 1 and the edge line of the orthographic projection of the third via hole 42 on the first base substrate 1 is greater than or equal to the spacing (D1 and D3) between the edge line of the orthographic projection of the first via hole 34 on the first base substrate 1 and the edge line of the orthographic projection of the second via hole 41 on the first base substrate 1; D1′ and D1 can be the spacing in the second direction Y, and D1′ is compared with D1; D3′ and D3 can be the spacing in the first direction X, and D3′ is compared with D3. It is also possible to compare D1′ with D3, and compare D1 with D3′.

It should be noted that, the orthographic projection of the recessed portion 33 on the first base substrate 1 refers to the orthographic projection of the side of the recessed portion 33 away from the first base substrate 1 on the first base substrate 1, that is, the orthographic projection of the topmost part of the recessed portion 33 on the first base substrate 1. The orthographic projection of the third via hole 42 on the first base substrate 1 refers to the orthographic projection of the side of the third via hole 42 away from the first base substrate 1 on the first base substrate 1, that is, the orthographic projection of the topmost part of the third via hole 42 on the first base substrate 1. The orthographic projection of the first via hole 34 on the first base substrate 1 refers to the orthographic projection of the side of the first via hole 34 away from the first base substrate 1 on the first base substrate 1, that is, the orthographic projection of the topmost part of the first via hole 34 on the first base substrate 1. The orthographic projection of the second via hole 41 on the first base substrate 1 refers to the orthographic projection of the side of the second via hole 41 away from the first base substrate 1 on the first base substrate 1, that is, the orthographic projection of the topmost part of the second via hole 41 on the first base substrate 1. The orthographic projections of other via holes on the first base substrate 1 all refer to the orthographic projections of the topmost parts on the first base substrate 1.

In order to set a large area of the recessed portion 33 in the third via hole 42, the area of the orthographic projection of the third via hole 42 on the first base substrate 1 is greater than or equal to the area of the orthographic projection of the second via hole 41 on the first base substrate 1. For example, when the third via hole 42 and the second via hole 41 are set to be the same rectangle, in the first direction X, the length of the third via hole 42 is greater than or equal to the length of the second via hole 41; in the second direction Y, the width of the third via hole 42 is greater than or equal to the width of the second via hole 41.

The material of the first electrode layer 4 can be ITO, and the thickness of the first electrode layer 4 is greater than or equal to 400 angstroms and less than or equal to 700 angstroms. For example, the thickness of the first electrode layer 4 can be 450 angstroms, 550 angstroms, 580 angstroms, 635 angstroms, 674 angstroms, etc. The material of the first electrode layer 4 can also be other transparent conductive materials.

Since the material of the first electrode layer 4 is a transparent conductive material, the first electrode layer 4 can be set as a whole layer, which will not affect the transmittance of the array substrate 100, and will not affect the luminous brightness of the display panel either. However, the resistivity of the transparent conductive material is relatively large, resulting in a large resistance of the first electrode layer 4, which makes the power consumption of the array substrate 100 large and the heat generation serious.

In this example embodiment, as shown in FIGS. 1 and 12, a conductive enhancement layer 5 is provided on the side of the first electrode layer 4 away from the first base substrate 1, and the orthographic projection of the conductive enhancement layer 5 on the first base substrate 1 is located within the orthographic projection of the first electrode layer 4 on the first base substrate 1, for example, the orthographic projection of the first electrode layer 4 on the first base substrate 1 covers and is larger than the orthographic projection of the conductive enhancement layer 5 on the first base substrate 1.

The material of the conductive enhancement layer 5 may be copper, and the thickness of the conductive enhancement layer 5 may be greater than or equal to 1000 angstroms and less than or equal to 2000 angstroms, for example, the thickness of the conductive enhancement layer 5 may be 1115 angstroms, 1200 angstroms, 1285 angstroms, 1358 angstroms, 1391 angstroms, 1425 angstroms, 1588 angstroms, 1638 angstroms, 1721 angstroms, 1785 angstroms, 1868 angstroms, 1926 angstroms, 1985 angstroms, and the like. In other example embodiments of the present disclosure, the material of the conductive enhancement layer 5 may also be other metal materials, such as aluminum and silver. The resistivity of the metal material is relatively small. By adding the conductive enhancement layer 5 on the side of the first electrode layer 4 away from the first base substrate 1, the resistance of the first electrode layer 4 can be reduced, thereby reducing the power consumption of the array substrate 100 and reducing the heat generation of the array substrate 100.

When etching the conductive enhancement material layer 50 to form the conductive enhancement layer 5, an ashing process is required. The ashing process will cause oxidation corrosion to the conductive enhancement material layer 50, thereby causing the first electrode material layer 40 to be etched when the conductive enhancement material layer 50 is etched to form the conductive enhancement layer 5, resulting in undesirable disconnection of the first electrode layer 4. A protective layer is provided on the conductive enhancement layer 5. When the mask layer 9 is ashed, the protective layer protects the conductive enhancement material layer 50 to avoid oxidation corrosion of the conductive enhancement material layer 50 during the ashing process, thereby avoiding etching the first electrode layer 4 when the first electrode material layer 40 is patterned to form the first electrode layer 4, resulting in undesirable disconnection of the first electrode layer 4. The material of the protective layer can be MoNbTi.

However, the conductive enhancement layer 5 made of metal is opaque. Therefore, the conductive enhancement layer 5 cannot be set as a whole layer, the conductive enhancement layer 5 should be set as far as possible at a position of the array substrate 100 that is not transparent inherently, so that the conductive enhancement layer 5 can not only reduce the resistance of the first electrode layer 4, but also will not affect the aperture ratio of the array substrate 100.

Specifically, as shown in FIGS. 12 and 15, the conductive enhancement layer 5 may include a first conductive strip 51 and a second conductive strip 52; the first conductive strip 51 extends along the first direction X, and the extension direction of the first conductive strip 51 is consistent with the extension direction of the gate line 221; the orthographic projection of the first conductive strip 51 on the first base substrate 1 overlaps at least partially with the orthographic projection of the gate line 221 on the first base substrate 1, for example, the orthographic projection of the first conductive strip 51 on the first base substrate 1 can be located within the orthographic projection of the gate line 221 on the first base substrate 1, that is, the width of the first conductive strip 51 in the second direction Y is less than or equal to the width of the gate line 221 in the second direction Y. In this way, the aperture ratio of the array substrate 100 can be guaranteed, thereby ensuring the display brightness of the display panel. Moreover, the number of the first conductive strips 51 can be the same as the number of the gate lines 221, that is, the first conductive strips 51 and the gate lines 221 are in a one-to-one correspondence; or, the number of the first conductive strips 51 can be less than the number of the gate lines 221. The number of the first conductive strips 51 can be set as one, two or more.

The number of the second conductive strips 52 can be set as one, in which case the second conductive strip 52 is connected to one end of the first conductive strip 51 in the first direction X. The number of the second conductive strips 52 can be set as two, one of which is connected to one end of the first conductive strip 51 in the first direction X, and the other thereof is cross-connected with the first conductive strip 51. The number of the second conductive strips 52 can be set as plural, one of which is connected to one end of the first conductive strip 51 in the first direction X, and the others thereof are cross-connected with the first conductive strip 51.

The second conductive strip 52 extends along the second direction Y, and the extension direction of the second conductive strip 52 is consistent with the extension direction of the data line 253. The orthographic projection of the second conductive strip 52 on the first base substrate 1 overlaps at least partially with the orthographic projection of the data line 253 on the first base substrate 1. For example, the orthographic projection of the second conductive strip 52 on the first base substrate 1 can be located within the orthographic projection of the data line 253 on the first base substrate 1, that is, the width of the second conductive strip 52 in the first direction X is less than or equal to the width of the data line 253 in the first direction X. Moreover, the number of the second conductive strips 52 can be less than the number of the data lines 253. The number of the second conductive strips 52 can also be equal to the number of the data lines 253, that is, the second conductive strips 52 and the data lines 253 are in a one-to-one correspondence.

The conductive enhancement layer 5 may also include a plurality of lead strips 53, one end of which may be connected to the second conductive strip 52, for example, one end of which may be connected to the outermost second conductive strip 52; the lead strip 53 extends along the first direction X toward the side away from the display region AA, and the extension direction of the lead strip 53 may be consistent with the extension direction of the gate line 221; the other end of the plurality of lead strips 53 may be connected to the edge GOA, GOA is a row scanning signal line, and is finally connected to the binding pin of the peripheral region WW, the Com signal may be input through the binding pin, the Com signal is a common electrode signal, and then the Com signal is transmitted to the conductive enhancement layer 5 and the first electrode layer 4 of the display region AA through the plurality of lead strips 53.

The orthographic projection of the lead strip 53 on the first base substrate 1 does not overlap with the orthographic projection of the gate line 221 on the first base substrate 1, that is, the lead strip 53 and the gate line 221 are not arranged directly opposite to each other, but are arranged in a staggered manner, to avoid generating parasitic capacitance between the lead strip 53 and the gate line 221.

The conductive enhancement layer 5 may also include a collection connection strip 54, which may be connected to one end of the lead strip 53 away from the second conductive strip 52. When the lead strip 53 is set as one, the one lead strip 53 is connected to the collection connection strip 54; when the lead strip 53 is set as two or more, the two or more lead strips 53 are connected to the collection connection strip 54. The collection connection strip 54 extends along the second direction Y, and the extension direction of the collection connection strip 54 may be consistent with the extension direction of the data line 253. The plurality of lead strips 53 are connected to the edge GOA through the collection connection strip. The common electrode signal can be first transmitted to the collection connection strip 54, and then transmitted to the lead strip 53 and the first electrode layer 4 through the collection connection strip 54.

Moreover, as shown in FIGS. 13 and 14, the spacing D2′ between the edge line of the orthographic projection of the third via hole 42 on the first base substrate 1 and the edge line of the orthographic projection of the adjacent first conductive strip 51 on the first base substrate 1 is greater than or equal to the spacing D2 between the edge line of the orthographic projection of the second via hole 41 on the first base substrate 1 and the edge line of the orthographic projection of the adjacent first conductive strip 51 on the first base substrate 1. The spacing between the edge line of the orthographic projection of the third via hole 42 on the first base substrate 1 and the adjacent first conductive strip 51 is greater than or equal to 0.5 microns and less than or equal to 3 microns. The spacing between the edge line of the orthographic projection of the second via hole 41 on the first base substrate 1 and the edge line of the orthographic projection of the adjacent first conductive strip 51 on the first base substrate 1 is greater than or equal to 2 microns and less than or equal to 5.5 microns.

The spacing D4′ between the edge line of the orthographic projection of the third via hole 42 on the first base substrate 1 and the edge line of the orthographic projection of the adjacent second conductive strip 52 on the first base substrate 1 is greater than or equal to the spacing D4 between the edge line of the orthographic projection of the second via hole 41 on the first base substrate 1 and the edge line of the orthographic projection of the adjacent second conductive strip 52 on the first base substrate 1. The spacing between the edge line of the orthographic projection of the third via hole 42 on the first base substrate 1 and the adjacent second conductive strip 52 is greater than or equal to 0.5 micrometers and less than or equal to 3 micrometers. The spacing between the edge line of the orthographic projection of the second via hole 41 on the first base substrate 1 and the edge line of the orthographic projection of the adjacent second conductive strip 52 on the first base substrate 1 is greater than or equal to 2 micrometers and less than or equal to 5.5 micrometers.

Such a configuration makes the distance between the second via hole 41 and the first conductive strip 51, the second conductive strip 52 large. Even if there are errors in the preparation process of forming the first conductive strip 51 and the second conductive strip 52 and the alignment precision fluctuates, the first conductive strip 51 and the second conductive strip 52 will not be formed in the second via hole 41, so that the defect that the first conductive strip 51 and the second conductive strip 52 are broken due to crossing the second via hole 41 will not occur, the defect of the abnormal pattern of the conductive enhancement layer 5 and the first electrode 4 due to the residue of the mask layer material in the second via hole 41 will not occur, and the defect of short-circuit caused by contact of the first electrode 4 and the second electrode 71 due to the residue in the first electrode 4 will be avoided.

Furthermore, the distance between the third via hole 42 and the first conductive strip 51, the second conductive strip 52 is large, even if there are errors in the preparation process of forming the first conductive strip 51 and the second conductive strip 52 and the alignment precision fluctuates, the first conductive strip 51 and the second conductive strip 52 will not be formed in the third via hole 42, so that the defect that the first conductive strip 51 and the second conductive strip 52 are broken due to crossing the third via hole 42 will not occur, the defect of the abnormal pattern of the conductive enhancement layer 5 and the first electrode 4 due to the residue of the mask layer material in the third via hole 42 will not occur, and the defect of short-circuit caused by contact of the first electrode 4 and the second electrode 71 due to the residue in the first electrode 4 will be avoided.

In addition, as shown in FIG. 12, the recessed portion 33 and the first via hole 34 in a row of pixel regions 26 arranged along the first direction X are located in substantially the same region in the corresponding pixel region 26, for example, the recessed portion 33 and the first via hole 34 in the first row of pixel regions 26 are located at the upper left corner of the pixel region 26, and the recessed portion 33 and the first via hole 34 in the second row of pixel regions 26 are located at the upper right corner of the pixel region 26. In some other example embodiments of the present disclosure, it may also be that the recessed portion 33 and the first via hole 34 in a row of pixel regions 26 arranged along the second direction Y are located at substantially the same position in the pixel region 26.

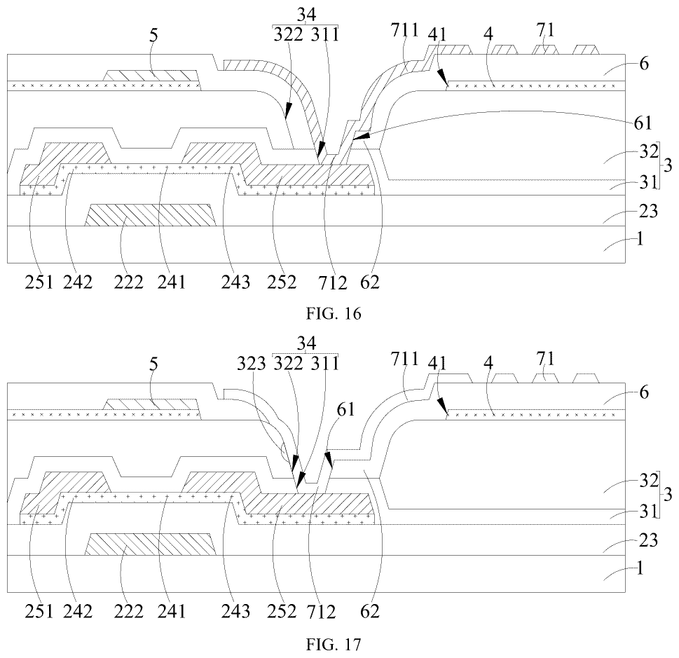

In this example embodiment, as shown in FIGS. 16 and 17, a second insulating layer 6 is provided on the side of the conductive enhancement layer 5 away from the first base substrate 1, and the second insulating layer 6 is formed in the seventh via hole 322 on the organic insulating layer 32 to form a recessed structure. A fourth via hole 61 is provided on the second insulating layer 6, and the orthographic projection of the seventh via hole 322 on the first base substrate 1 covers and is larger than the orthographic projection of the fourth via hole 61 on the first base substrate 1, that is, the fourth via hole 61 is connected with seventh via hole 322, and the seventh via hole 322 on the organic insulating layer 32 is larger than the fourth via hole 61 on the second insulating layer 6, so that the second insulating layer 6 not only covers the hole sidewall of the seventh via hole 322, but also covers a part of the first insulating layer 31 in the seventh via hole 322 that is not covered by the organic insulating layer 32, that is, the fourth via hole 61 does not completely occupy the bottom wall of the recessed structure, so that the second insulating layer 6 forms a step portion 62 in the seventh via hole 322, or it can be said that the step portion 62 is the residue of the second insulating layer 6 on the hole bottom wall of the seventh via hole 322.

A second electrode layer 7 is provided on the side of the second insulating layer 6 away from the first base substrate 1, and the second electrode 71 can be a pixel electrode. The second electrode layer 7 includes a plurality of second electrodes 71, and the second electrode 71 includes a main body 711 and a connection portion 712 connected to each other. The connection portion 712 is connected to the drain 243 of the switch unit 21 through the fourth via hole 61 and the fifth via hole 311, that is, the part located in the fourth via hole 61 and the fifth via hole 311 is the connection portion 712; and the main body 711 is located on the side of the step portion 62 away from the first base substrate 1, or it can be said that the main body 711 is located on the side of the fourth via hole 61 provided with the step portion 62, that is, the part arranged on the side of the second insulating layer 6 away from the first base substrate 1 and close to the step portion 62 is the main body 711.

With such arrangement, even if there are errors in the processing device and the alignment process during the formation of the fourth via hole 61, as shown in FIG. 16, if the formed fourth via hole 61 is offset to the side where the step portion 62 is to be formed, due to sufficient margin, when the second insulating layer 6 is etched, the second insulating layer 6 covering the hole sidewall of the seventh via hole 322 close to the step portion 62 will not be etched, so that the second insulating layer 6 forms a complete protection for the organic insulating layer 32, and will not etch the organic insulating layer 32, and will not form a cavity 323 on the organic insulating layer 32, and the subsequently formed second electrode 71 will not cover the cavity 323, and the second electrode 71 will not have the risk of breaking or falling off; as shown in FIG. 17, if the formed fourth via hole 61 is offset to the other sides where the step portion 62 does not need to be formed, when the second insulating layer 6 is etched, the second insulating layer 6 covering the hole sidewall of the seventh via hole 322 on the other sides will be etched, so that the second insulating layer 6 will not form a complete protection for the organic insulating layer 32, and the organic insulating layer 32 will be etched, and a cavity 323 will be formed on the organic insulating layer 32, and a part of the subsequently formed second electrode 71 will cover the cavity 323, but since the main body 711 is not covered at the cavity 323, the main body 711 will not have the risk of breaking or falling off; and it will not affect the connection between the main body 711 and the connection portion 712, and will not affect the transmission of signals from the drain connection lead 252 to the second electrode 71.

The material of the second insulating layer 6 can be an inorganic material, for example, it can be silicon nitride, silicon oxide, etc. The thickness of the second insulating layer 6 is greater than or equal to 100 nm and less than or equal to 500 nm.

The material of the second electrode 71 may be ITO, and the thickness of the second electrode 71 may be greater than or equal to 400 angstroms and less than or equal to 700 angstroms. For example, the thickness of the first electrode may be 450 angstroms, 550 angstroms, 580 angstroms, 635 angstroms, 674 angstroms, etc. The material of the second electrode 71 may also be other transparent conductive materials.

In addition, in other example embodiments of the present disclosure, the positions of the first electrode layer 4 and the second electrode layer 7 may be interchanged, specifically, the second electrode 71 may be provided on the side of the organic insulating layer 32 away from the base substrate, the second electrode 71 may be a pixel electrode, and the second electrode 71 is connected to the drain 243 through the fifth via hole 311 on the first insulating layer 31 and the seventh via hole 322 on the organic insulating layer 32; the second insulating layer 6 is provided on the side of the second electrode 71 away from the base substrate; the first electrode layer 4 and the conductive enhancement layer 5 are sequentially stacked on the side of the second insulating layer 6 away from the base substrate; the specific structures of the first electrode layer 4 and the conductive enhancement layer 5 have been described in detail above, so they will not be repeated here.

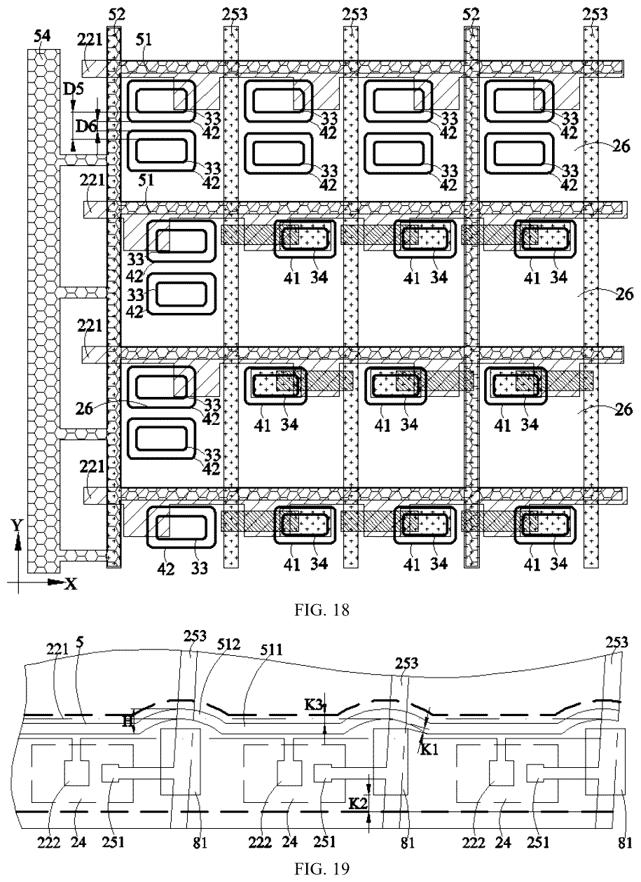

As shown in FIG. 18, in some other example embodiments of the present disclosure, at least two recessed portions 33 are provided in a pixel region 26 of the transition region DUM, for example, two, three or more recessed portions 33 may be provided in a pixel region 26 of the transition region DUM; and at least two third via holes 42 are provided therein, for example, two, three or more third via holes 42 may be provided in a pixel region 26 of the transition region DUM; the third via holes 42 correspond to the recessed portions 33 one by one, and the number of the third via holes 42 is the same as the number of the recessed portions 33.

The spacing D5 between two adjacent recessed portions 33 in the same pixel region 26 is greater than or equal to 4 microns, and the spacing D6 between two adjacent third via holes 42 in the same pixel region 26 is greater than or equal to 2 microns.

It should be noted that, the spacing between the two adjacent recessed portions 33 and the spacing between the two adjacent third via holes 42 are set according to the precision of the device, which avoids the two adjacent recessed portions 33 being connected to form one recessed portion 33, and avoids the two adjacent third via holes 42 being connected to form one third via hole 42. Therefore, when the precision of the device is high, the spacing between two adjacent recessed portions 33 and the spacing between two adjacent third via holes 42 can be set smaller.

A first via hole 34 is provided in a pixel region 26 of the display region AA, and a second via hole 41 is provided therein, that is, the specific structure of the display region AA is the same as the structure of the above-mentioned example embodiment, which is not repeated here.

As shown in FIG. 19, the array substrate 100 may also include a first spacer 81, and the first spacer 81 is provided on the side of the second electrode layer 7 away from the first base substrate 1.

The first spacer 81 can be set to a square frustum structure, that is, the cross-section of the first spacer 81 parallel to the first base substrate 1 is a rectangle, and the area of the bottom surface close to the first base substrate 1 is larger than the area of the top surface away from the first base substrate 1.

Generally, a relatively flat plane can be provided between two adjacent switch units 21 (thin film transistors), for providing the first spacer 81, so the first spacer 81 is located between two adjacent switch units 21; the length direction of the first spacer 81 is consistent with the extension direction of the data line 253, and the orthographic projection of the first spacer 81 on the first base substrate 1 overlaps with the orthographic projection of the data line 253 on the first base substrate 1, that is, the first spacer 81 is arranged opposite to the data line 253.

The orthographic projection of the first conductive strip 51 of the conductive enhancement layer 5 on the first base substrate 1 is set as a curve, specifically, the curve can include a plurality of straight lines and a plurality of arcs, and the straight lines and arcs are alternately arranged and connected to each other. The first conductive strip 51 is bent toward the side away from the first spacer 81 at a position adjacent to the first spacer 81, that is, the arc is bent toward the side away from the first spacer 81, and the bending depth H is greater than or equal to 2 microns and less than or equal to 3 microns. For example, the bending depth H can be 2.5 microns. The bending depth H is the maximum distance between the arc and the straight line. The specific value of the bending depth H can be set according to the device and process precision. Moreover, the bending position of the first conductive strip 51 is generally the position where it intersects with the data line 253.

Specifically, the first conductive strip 51 may include a first straight portion 511 and a first curved portion 512, the orthographic projection of the first straight portion 511 on the first base substrate 1 is located within the orthographic projection of the gate line 221 on the first base substrate 1, and the orthographic projection of the first curved portion 512 on the first base substrate 1 at least partially does not overlap with the orthographic projection of the gate line 221 on the first base substrate 1, that is, the orthographic projections of the two ends of the first curved portion 512 connected to the first straight portion 511 on the first base substrate 1 are located within the orthographic projection of the gate line 221 on the first base substrate 1, but the orthographic projection of the middle part of the first curved portion 512 on the first base substrate 1 does not overlap with the orthographic projection of the gate line 221 on the first base substrate 1.

After the first conductive strip 51 is bent, space is reserved for the first spacer 81. Because the first spacer 81 is used to support the color filter substrate 200, a relatively flat support plane needs to be set. Therefore, a relatively flat base plane needs to be provided for the first spacer 81. The first conductive strip 51 will cause the base plane for setting the first spacer 81 to be uneven. After the first conductive strip 51 is bent, the first spacer 81 does not need to be set on the side of the first conductive strip 51 away from the first base substrate 1, so as to provide a relatively flat base plane for the first spacer 81.

In some other example embodiments of the present disclosure, the first conductive strip 51 may not bypass the first spacer 81, so that the orthographic projection of the first conductive strip 51 on the first base substrate 1 overlaps with the orthographic projection of the first spacer 81 on the first base substrate 1.

Moreover, the minimum distance K1 between the first spacer 81 and the first conductive strip 51 is greater than or equal to 2 microns and less than or equal to 4 microns. The specific value of the minimum distance between the first spacer 81 and the first conductive strip 51 can be specifically set according to the device and process precision. Prevent the situation where, due to process or device errors, the first spacer 81 is provided on the side of the first conductive strip 51 away from the first base substrate, resulting in an uneven base surface of the first spacer 81. Moreover, both the first spacer 81 and the first conductive strip 51 need to be shielded by the black matrix 202, to minimize the area of the black matrix 202, and increase the aperture ratio.

It should be noted that, the above curves are not necessarily all composed of arcs, but can also be a broken line formed by a plurality of straight lines, or a mixture of straight lines and arcs.

Moreover, the curved first conductive strip 51 has sufficient extension margin, which can effectively avoid the breakage of the first conductive strip 51.

In addition, in some further example embodiments of the present disclosure, the distance between the edge line of a side of the recessed portion 33 close to the display region AA and the display region AA is greater than the distance between the edge line of a side of the recessed portion 33 close to the peripheral region WW and the peripheral region WW. That is, the recessed portion 33 is closer to the peripheral region WW, which facilitates the material of the mask layer of the peripheral region WW to flow into the recessed portion 33, and avoids the material of the mask layer of the display region AA from flowing into the recessed portion 33 as much as possible, resulting in thinning of the thickness of the mask layer of the display region AA.

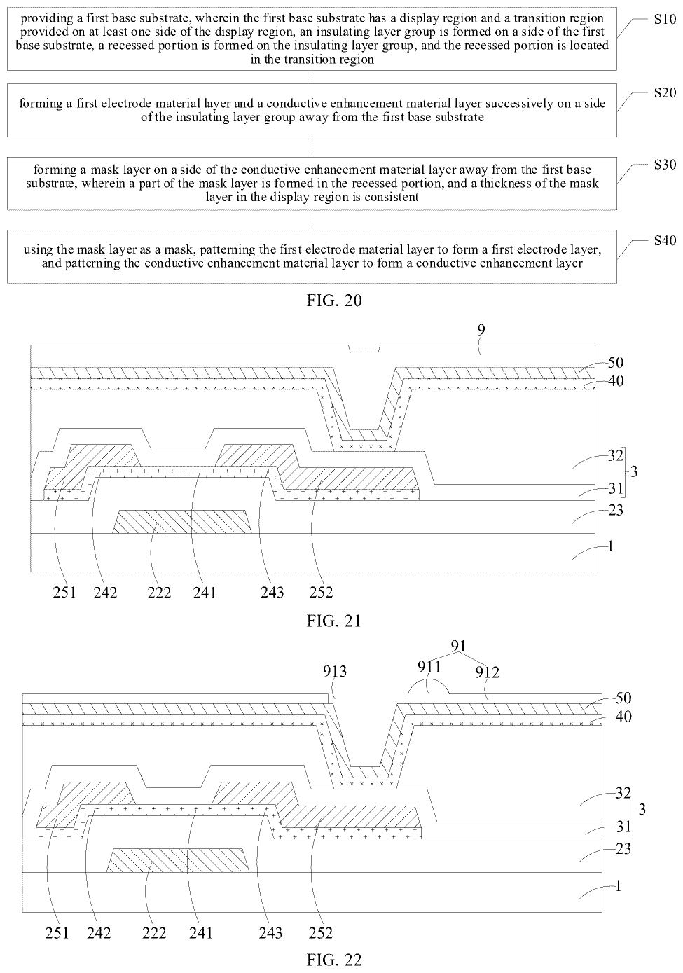

Based on the same inventive concept, the example embodiment of the present disclosure also provides a method for preparing an array substrate 100. As shown in FIG. 20, the method for preparing the array substrate 100 may include the following steps:

Step S10, providing a first base substrate, wherein the first base substrate has a display region and a transition region provided on at least one side of the display region, an insulating layer group is formed on a side of the first base substrate, a recessed portion is formed on the insulating layer group, and the recessed portion is located in the transition region;

Step S20, forming a first electrode material layer and a conductive enhancement material layer successively on a side of the insulating layer group away from the first base substrate;

Step S30, forming a mask layer on a side of the conductive enhancement material layer away from the first base substrate, wherein a part of the mask layer is formed in the recessed portion, and a thickness of the mask layer in the display region is consistent; and

Step S40, using the mask layer as a mask, patterning the first electrode material layer to form a first electrode layer, and patterning the conductive enhancement material layer to form a conductive enhancement layer.

The various steps of the method for preparing the array substrate 100 are described in detail below.

Referring to FIG. 1, a first base substrate 1 is provided, the first base substrate 1 has a display region AA and a transition region DUM provided on at least one side of the display region AA, the display region AA of the first base substrate 1 is also the display region AA of the array substrate 100, and the transition region DUM of the first base substrate 1 is also the transition region DUM of the array substrate 100. The first base substrate 1 also has a peripheral region WW, and the peripheral region WW of the first base substrate 1 is also the peripheral region WW of the array substrate 100. The specific structure has been described in detail above, so it will not be repeated here.

A gate layer 22 is formed on one side of the first base substrate 1, and the gate layer 22 may include a gate 222 and a gate line 221; a gate insulating layer 23 is formed on the side of the gate layer 22 away from the first base substrate 1; an active layer 24 is formed on the side of the gate insulating layer 23 away from the first base substrate 1, and the active layer 24 may include a channel portion 241, a source 242 and a drain 243, and the source 242 and the drain 243 are connected to opposite sides of the channel portion 241; a connecting conductor layer 25 is formed on the side of the active layer 24 away from the first base substrate 1, and the connecting conductor layer 25 may include a plurality of source connection leads 251, a plurality of drain connection leads 252 and a plurality of data lines 253.

A first insulating layer 31 and an organic insulating layer 32 are formed successively on the side of the connecting conductor layer 25 away from the first base substrate 1, and the organic insulating layer 32 is patterned to form a sixth via hole 321 and a seventh via hole 322, the seventh via hole 322 is located in the display region AA, and the sixth via hole 321 is located in the transition region DUM; the material of the organic insulating layer 32 can be photoresist, and when the sixth via hole 321 and the seventh via hole 322 are formed on the organic insulating layer 32, only exposure and development are required, and etching is not required, and the process is relatively simple. The sixth via hole 321 forms a recessed portion 33.

The area of the orthographic projection of the first via hole 34 on the first base substrate 1 is less than or equal to the area of the orthographic projection of the recessed portion 33 on the first base substrate 1.

The first electrode material layer 40 can be formed by sputtering on the side of the insulating layer group 3 away from the first base substrate 1, and the conductive enhancement material layer 50 can be formed by sputtering on the side of the first electrode material layer 40 away from the first base substrate 1; the first electrode material layer 40 and the conductive enhancement material layer 50 will be formed in the first via hole 34 and the recessed portion 33, and the first electrode material layer 40 located in the first via hole 34 is connected to the drain 243, but the first electrode material layer 40 eventually forms a common electrode and does not need to be connected to the drain 243. Therefore, the first electrode material layer 40 needs to be patterned, and the conductive enhancement material layer 50 is made of metal, which is opaque, which avoids the conductive enhancement material layer 50 affecting the transmittance of the array substrate 100, the conductive enhancement material layer 50 also needs to be patterned.

As shown in FIG. 21, a mask layer 9 is formed on the side of the conductive enhancement material layer 50 away from the first base substrate 1 by a coating or printing process. Since the material of the mask layer 9 has certain fluidity, it will flow from a higher height area to a lower height area. Since the peripheral region WW is provided with a large area of peripheral leads 233, the height of the peripheral region WW is higher than the height of the display region AA and the height of the transition region DUM. Therefore, the material of the mask layer 9 will flow from the peripheral region WW to the transition region DUM and the display region AA, resulting in a thicker thickness of the mask layer 9 in the edge area of the display region AA close to the transition region DUM.

After the recessed portion 33 is provided in the transition region DUM, the material of the mask layer 9 will flow from the peripheral region WW to the transition region DUM, and then flow into the recessed portion 33, thereby preventing the material of the mask layer 9 from further flowing to the display region AA, so that the thickness of the mask layer 9 in the display region AA is consistent, which avoids the thickness of the mask layer 9 in the edge area of the display region AA close to the transition region DUM being thick.

Specifically, a mask plate is placed on the side of the mask layer 9 away from the base substrate, and the mask plate may include a light transmitting portion, a light shielding portion, and a semi-light transmitting portion; the semi-light transmitting portion is arranged opposite to the second portion 912, that is, the orthographic projection of the semi-light transmitting portion on the base substrate coincides with the orthographic projection of the second portion 912 on the base substrate; the light shielding portion is arranged opposite to the first portion 911, that is, the orthographic projection of the light shielding portion on the base substrate coincides with the orthographic projection of the first portion 911 on the base substrate. The light transmitting portion is arranged opposite to other portions of the mask layer 9.

Then, as shown in FIG. 22, the mask layer 9 is exposed and developed to form a mask pattern 91, and the mask layer 9 arranged opposite to the light transmitting portion is removed to form a ninth via hole 913, and the ninth via hole 913 exposes a part of the conductive enhancement material layer 50; the mask layer 9 arranged opposite to the semi-light transmitting portion is removed by a certain thickness, to form the second portion 912; the mask layer 9 arranged opposite to the light shielding portion is completely retained, to form the first portion 911, so that the thickness of the first portion 911 is greater than the thickness of the second portion 912. Moreover, since the overall thickness of the display region AA of the mask layer 9 is relatively uniform, the situation shown in FIG. 2 where the second portion 912 is thick will not occur.

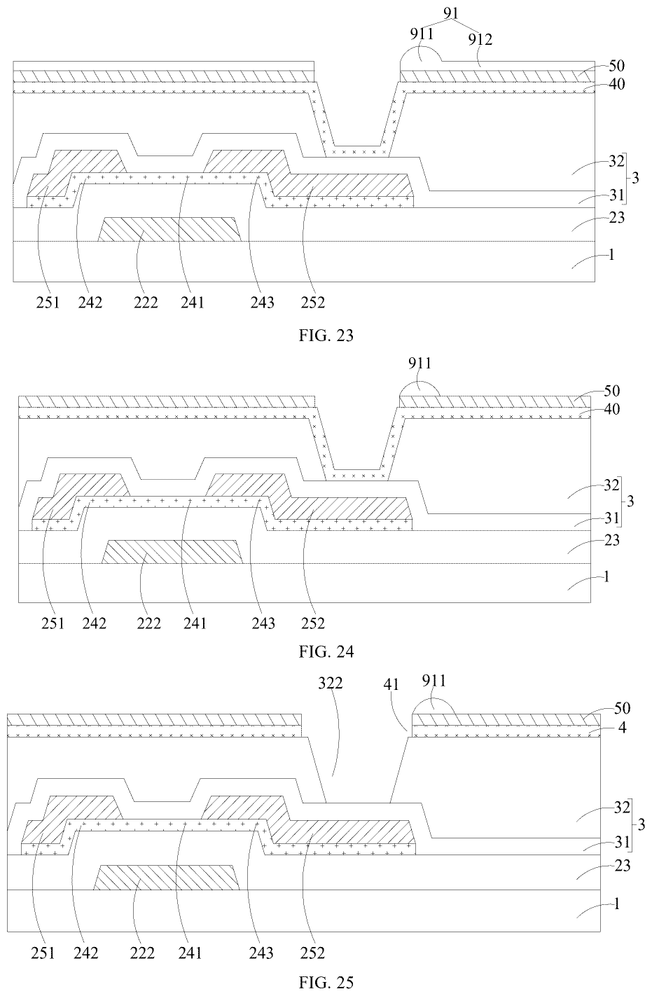

Finally, as shown in FIG. 23, the part of the conductive enhancement material layer 50 opposite to the ninth via hole 913 is etched and removed, that is, the exposed conductive enhancement material layer 50 is etched for the first time, and the conductive enhancement material layer 50 covered by the mask pattern 91 is retained.

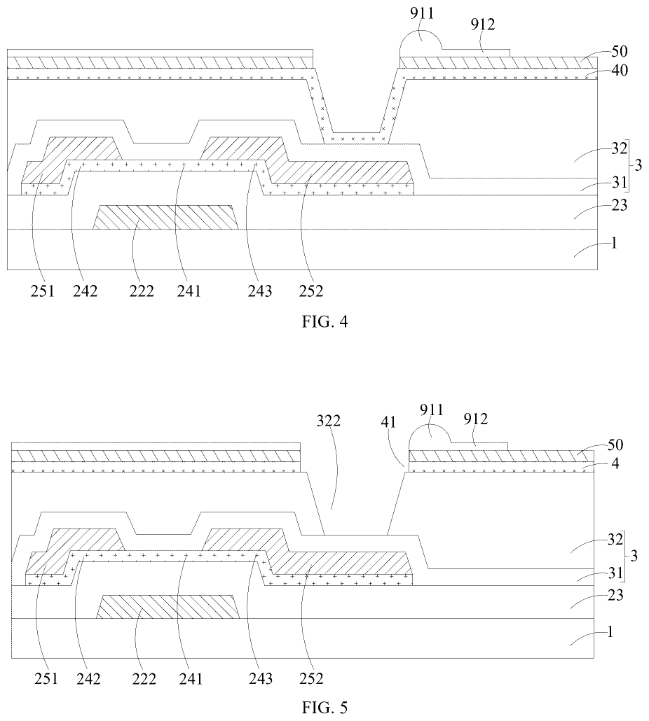

As shown in FIG. 24, the mask pattern 91 is ashed to remove the second portion 912, so that the conductive enhancement material layer 50 covered by the second portion 912 is exposed, and the gas used in the ashing process may include SF₆ and O₂. The second portion 912 is removed by the ashing process, so that the conductive enhancement material layer 50 covered by the second portion 912 is exposed, and the thickness of the first portion 911 is also reduced. Moreover, since the overall thickness of the display region AA of the mask layer 9 is relatively uniform, the situation shown in FIG. 4 where a part of the second portion 912 remains will not occur.

Referring to FIG. 25, the part of the first electrode material layer 40 opposite to the ninth via hole 913 is etched and removed, to form the first electrode layer 4; specifically, the first electrode material layer 40 is etched by using the first portion 911 and the conductive enhancement material layer 50 as a mask to form the first electrode layer 4, that is, the first electrode material layer 40 is etched on the first electrode layer 4 to form the second via hole 41 and the third via hole 42.

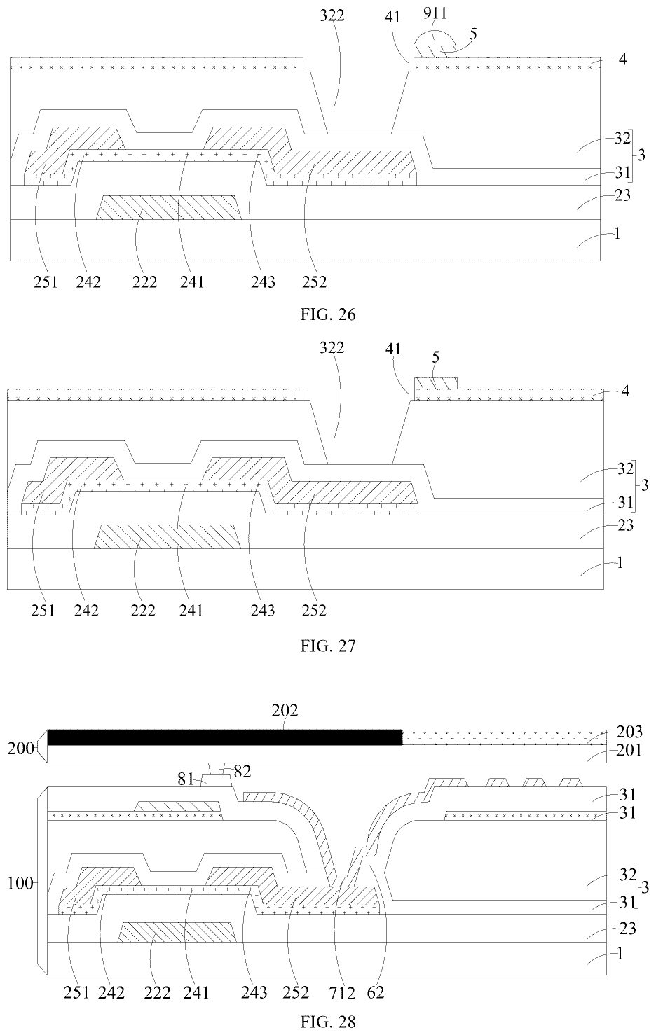

Referring to FIG. 26, the remaining conductive enhancement material layer 50 is patterned to form the conductive enhancement layer 5, specifically, the conductive enhancement material layer 50 is etched by using the first portion 911 as a mask to form the conductive enhancement layer 5. The orthographic projection of the conductive enhancement layer 5 on the base substrate overlaps with the orthographic projection of the gate line 221 on the base substrate, specifically, the orthographic projection of the conductive enhancement layer 5 on the base substrate is located within the orthographic projection of the gate line 221 on the base substrate, that is, the extension direction of the conductive enhancement layer 5 is consistent with the extension direction of the gate line 221, and the width of the conductive enhancement layer 5 is slightly smaller than the width of the gate line 221. The width of the conductive enhancement layer 5 is about 3.5 microns, and the width of the gate line 221 is about 4.5 microns. Since the conductive enhancement layer 5 is made of metal, it is opaque and reflective. Therefore, in order to avoid its reflection and affecting the display effect, it is necessary to shield it through the black matrix 202, and the gate line 221 is also shielded by the black matrix 202, the orthographic projection of the conductive enhancement layer 5 on the base substrate is located within the orthographic projection of the gate line 221 on the base substrate, which can avoid increasing the width of the black matrix 202, thereby avoiding reducing the aperture ratio.

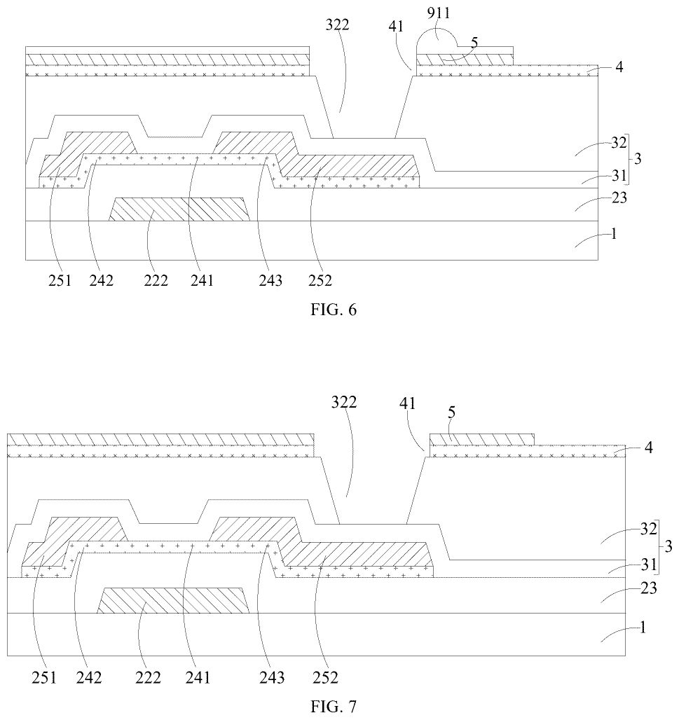

Moreover, since the overall thickness of the display region AA of the mask layer 9 is relatively uniform, the situation shown in FIG. 6 that a part of the conductive enhancement layer 5 remains will not occur, that is, the situation shown in FIG. 6 that the width of the conductive enhancement layer 5 is wide will not occur.

Referring to FIG. 27, the remaining mask layer 9 is removed, that is, the remaining first portion 911 is peeled off.

A second insulating layer 6 is formed on the side of the conductive enhancement layer 5 away from the first base substrate 1, and the second insulating layer 6 and the first insulating layer 31 are etched by the same patterning process, and a fifth via hole 311 is formed on the first insulating layer 31, and a fourth via hole 61 is formed on the second insulating layer 6.

Finally, a second electrode material layer is formed on the side of the second insulating layer 6 away from the first base substrate 1, and the second electrode material layer is patterned to form a plurality of second electrodes 71.

It should be noted that, although the steps of the preparation method of the array substrate 100 in the present disclosure are described in a specific order in the accompanying drawings, this does not require or imply that these steps must be performed in this specific order, or that all the steps shown must be performed to achieve the desired result. Additionally or alternatively, some steps may be omitted, multiple steps may be combined into one step, and/or one step may be decomposed into multiple steps for execution, etc.

Based on the same inventive concept, the example embodiment of the present disclosure also provides a display panel, as shown in FIG. 28, the display panel may include an array substrate 100 and a color filter substrate 200; the array substrate 100 is any of the array substrates 100 described above; the specific structure of the array substrate 100 has been described in detail above, so it will not be repeated here. The color filter substrate 200 is arranged opposite to the array substrate 100, and the color filter substrate 200 may include a black matrix 202, and the orthographic projection of the conductive enhancement layer 5 on the first base substrate 1 is located within the orthographic projection of the black matrix 202 on the first base substrate 1.

In this example embodiment, the color filter substrate 200 may also include a second base substrate 201, a plurality of filter portions 203 and a black matrix 202 disposed on one side of the second base substrate 201, and the plurality of filter portions 203 are arranged in an array on one side of the second base substrate 201; the plurality of filter portions 203 may include a red filter portion 203, a blue filter portion 203, and a green filter portion 203.

A second spacer 82 is provided on the side of the color filter substrate 200 close to the array substrate 100. The second spacer 82 can also be set in a long strip shape. After the cell assembly, the second spacer 82 contacts the first spacer 81 and forms a cross structure. The second spacer 82 and the first spacer 81 together support the color filter substrate 200 to provide storage space for the liquid crystal.

Referring to FIG. 19, the thick black dotted line in the drawing is the edge line of the black matrix 202. When the first conductive strip 51 on the array substrate 100 is set as a curve, an edge line of the side of the black matrix 202 close to the first conductive strip 51 is set as a curve adapted to the first conductive strip 51, so that the black matrix 202 can not only shield the first conductive strip 51, but also will not increase the opaque area too much, thereby ensuring the light transmittance and brightness of the display panel.

The orthographic projection of the first spacer 81 on the first base substrate 1 is located within the orthographic projection of the black matrix 202 on the first base substrate 1; so that the black matrix 202 shields the first spacer 81; besides, the minimum distance K2 between the edge line of the orthographic projection of the first spacer 81 on the first base substrate 1 and the edge line of the orthographic projection of the black matrix 202 on the first base substrate 1 is greater than or equal to 2 microns and less than or equal to 4 microns. Prevent a situation where, due to process or device errors, the black matrix 202 fails to shield the first spacer 81.

The orthographic projection of the first conductive strip 51 on the first base substrate 1 is located within the orthographic projection of the black matrix 202 on the first base substrate 1; so that the black matrix 202 shields the first conductive strip 51; the minimum distance K3 between the edge line of the orthographic projection of the first conductive strip 51 on the first base substrate 1 and the edge line of the orthographic projection of the black matrix 202 on the first base substrate 1 is greater than or equal to 2 microns and less than or equal to 4 microns. Prevent a situation where, due to process or device errors, the black matrix 202 fails to shield the first conductive strip 51.

Moreover, both the first spacer 81 and the first conductive strip 51 need to be shielded by the black matrix 202, so as to minimize the area of the black matrix 202 and improve the aperture ratio.

The orthographic projection of the second conductive strip 52 on the first base substrate 1 is located within the orthographic projection of the black matrix 202 on the first base substrate 1; so that the black matrix 202 shields the second conductive strip 52.

The above values can be specifically set according to the device and process precision.

Based on the same inventive concept, the example embodiment of the present disclosure also provides a display apparatus, which may include the display panel described above. The specific structure of the display panel has been described in detail above, so it will not be repeated here.

The specific type of the display apparatus is not particularly limited, and any type of display apparatus commonly used in the field can be used, such as mobile devices such as mobile phones, wearable devices such as watches, VR apparatuses, etc. Those skilled in the art can make corresponding choices according to the specific purpose of the display apparatus, which will not be repeated here.

It should be noted that, in addition to the display panel, the display apparatus also includes other necessary components and components. Taking the display as an example, such as a housing, a circuit board, a power cord, etc., those skilled in the art can make corresponding supplements according to the specific use requirements of the display apparatus, which will not be repeated here.

Compared with the prior art, the beneficial effects of the display apparatus provided by the example embodiment of the present disclosure are the same as the beneficial effects of the array substrate 100 provided by the above example embodiments, which will not be repeated here.

After considering the specification and practicing the disclosure disclosed herein, those skilled in the art will easily think of other embodiments of the present disclosure. This application is intended to cover any variation, use or adaptive change of the present disclosure, which follows the general principles of the present disclosure and includes common knowledge or conventional technical means in the technical field of the present disclosure that are not disclosed in the present disclosure. The description and embodiments are only regarded as exemplary, and the true scope and spirit of the present disclosure are indicated by the attached claims.

1. An array substrate, having a display region and a transition region provided on at least one side of the display region, wherein the array substrate comprises:
a first base substrate;
an insulating layer group, provided on a side of the first base substrate, wherein a recessed portion is provided on the insulating layer group, and the recessed portion is located in the transition region;
a first electrode layer, provided on a side of the insulating layer group away from the first base substrate; and
a conductive enhancement layer, provided on a side of the first electrode layer away from the first base substrate, wherein an orthographic projection of the conductive enhancement layer on the first base substrate is located within an orthographic projection of the first electrode layer on the first base substrate.

2. The array substrate according to claim 1, wherein a first via hole is further provided on the insulating layer group, the first via hole is located in the display region, and an area of an orthographic projection of the first via hole on the first base substrate is equal to or smaller than an area of an orthographic projection of the recessed portion on the first base substrate.

3. The array substrate according to claim 2, wherein a second via hole and a third via hole are provided on the first electrode layer, the second via hole is located in the display region, the third via hole is located in the transition region, the orthographic projection of the recessed portion on the first base substrate is located within an orthographic projection of the third via hole on the first base substrate, and the orthographic projection of the first via hole on the first base substrate is located within an orthographic projection of the second via hole on the first base substrate.

4. The array substrate according to claim 3, wherein an area of the orthographic projection of the third via hole on the first base substrate is greater than or equal to an area of the orthographic projection of the second via hole on the first base substrate,
wherein a spacing between an edge line of the orthographic projection of the recessed portion on the first base substrate and an edge line of the orthographic projection of the third via hole on the first base substrate is greater than or equal to a spacing between an edge line of the orthographic projection of the first via hole on the first base substrate and an edge line of the orthographic projection of the second via hole on the first base substrate.

5. (canceled)

6. The array substrate according to claim 3, wherein the conductive enhancement layer comprises:
a first conductive strip, extending along a first direction;
a second conductive strip, extending along a second direction, wherein the second direction intersects with the first direction, and the first direction and the second direction are parallel to a side of the first base substrate close to the insulating layer group,
wherein a spacing between an edge line of the orthogonal projection of the third via hole on the first base substrate and an edge line of an orthogonal projection of an adjacent first conductive strip on the first base substrate is greater than or equal to a spacing between an edge line of the orthogonal projection of the second via hole on the first base substrate and an edge line of an orthogonal projection of an adjacent first conductive strip on the first base substrate;
and a spacing between the edge line of the orthogonal projection of the third via hole on the first base substrate and an edge line of an orthogonal projection of an adjacent second conductive strip on the first base substrate is greater than or equal to a spacing between an edge line of the orthogonal projection of the second via hole on the first base substrate and an edge line of an orthogonal projection of an adjacent second conductive strip on the first base substrate.

7. (canceled)

8. The array substrate according to claim 63, wherein the conductive enhancement layer comprises:
a first conductive strip, extending along a first direction;
a second conductive strip, extending along a second direction, wherein the second direction intersects with the first direction, and the first direction and the second direction are parallel to a side of the first base substrate close to the insulating layer group,
wherein the array substrate further comprises:
a switch layer group, provided between the first base substrate and the insulating layer group, the switch layer group comprising:
a plurality of switch units, provided in an array;
a plurality of gate lines, extending along the first direction, wherein each of the gate lines is located between two adjacent switch units, an orthographic projection of the first conductive strip on the first base substrate at least partially overlaps with an orthographic projection of the gate line on the first base substrate;
a plurality of data lines, extending along the second direction, wherein each of the data lines is located between two adjacent switch units, an orthographic projection of the second conductive strip on the first base substrate at least partially overlaps with an orthographic projection of the data line on the first base substrate, and the plurality of gate lines and the plurality of data lines intersect to form a plurality of pixel regions.

9. The array substrate according to claim 8, wherein at least two recessed portions and at least two third via holes are provided in one of the pixel regions in the transition region; one first via hole and one second via hole are provided in one of the pixel regions in the display region.

10. (canceled)

11. The array substrate according to claim 8, wherein only one row of pixel regions arranged along the first direction is arranged in the transition region on a side of the second direction of the display region, and only one column of pixel regions arranged along the second direction is arranged in the transition region on a side of the first direction of the display region.

12. The array substrate according to claim 8, wherein in the transition region, the switch unit does not include a drain and a drain connection lead, and the orthographic projection of the recessed portion on the first base substrate does not overlap with the switch unit.

13. The array substrate according to claim 12, wherein a distance between a lowest point of the recessed portion and the first base substrate is smaller than a distance between a lowest point of the first via hole and the first base substrate.

14. The array substrate according to claim 8, wherein the conductive enhancement layer further comprises:
a plurality of lead strips, wherein an end of the lead strip is connected to the second conductive strip, and the lead strip extends along the first direction toward a side away from the display region,
wherein an orthographic projection of the lead strip on the first base substrate does not overlap with the orthographic projection of the gate line on the first base substrate,
wherein the conductive enhancement layer further comprises:
a collection connection strip, connected to an end of the lead strip away from the second conductive strip, the collection connection strip extending along the second direction.

15-16. (canceled)

17. The array substrate according to claim 8, wherein two data lines are provided between orthographic projections of two adjacent second conductive strips on the first base substrate.

18. The array substrate according to claim 8, wherein the insulating layer group comprises:
a first insulating layer, provided on a side of the first base substrate, wherein a fifth via hole is provided on the first insulating layer, the fifth via hole is located in the display region and is connected to the switch unit;
an organic insulating layer, provided on a side of the first insulating layer away from the first base substrate, wherein a sixth via hole and a seventh via hole are provided on the organic insulating layer, the sixth via hole is the recessed portion, and the seventh via hole is connected with the fifth via hole to form the first via hole.

19. The array substrate according to claim 18, further comprising:
a second insulating layer, provided on a side of the conductive enhancement layer away from the first base substrate, wherein a fourth via hole is provided on the second insulating layer, an orthographic projection of the seventh via hole on the first base substrate covers and is larger than an orthographic projection of the fourth via hole on the first base substrate, the second insulating layer covers a hole sidewall of the seventh via hole, and covers a part of the first insulating layer exposed in the seventh via hole, such that the second insulating layer forms a step portion in the seventh via hole;
a second electrode layer, provided on a side of the second insulating layer away from the first base substrate, wherein the second electrode layer comprises a plurality of second electrodes, the second electrode comprises a main body portion and a connecting portion connected to each other, the connecting portion is connected to the switch unit through the fourth via hole and the fifth via hole, and the main body portion is located on a side of the step portion away from the first base substrate.

20. The array substrate according to claim 19, further comprising:
a first spacer, provided on a side of the second electrode layer away from the first base substrate and located between two adjacent switch units;
the orthographic projection of the first conductive strip on the first base substrate is provided as a curve, and the first conductive strip is bent toward a side away from the first spacer at a position adjacent to the first spacer.

21. The array substrate according to claim 20, wherein the orthographic projection of the first conductive strip on the first base substrate does not overlap with an orthographic projection of the first spacer on the first base substrate.

22. The array substrate according to claim 20, wherein the first conductive strip comprises a first straight portion and a first curved portion, an orthographic projection of the first straight portion on the first base substrate is located within the orthographic projection of the gate line on the first base substrate, and an orthographic projection of the first curved portion on the first base substrate at least partially does not overlap with the orthographic projection of the gate line on the first base substrate.

23. The array substrate according to claim 1, wherein the array substrate further comprises a peripheral region, the peripheral region is provided on a side of the transition region away from the display region, the peripheral region is provided with a plurality of peripheral leads, in a third direction, a height of the insulating layer group in the peripheral region is higher than a height of the insulating layer group in the display region, and the third direction is perpendicular to a side of the first base substrate close to the insulating layer group,
wherein a distance between an edge line of a side of the recessed portion close to the display region and the display region is greater than a distance between an edge line of a side of the recessed portion close to the peripheral region and the peripheral region.

24. (canceled)

25. The array substrate according to claim 1, wherein the orthographic projection of the conductive enhancement layer on the first base substrate does not overlap with an orthographic projection of the recessed portion on the first base substrate,
wherein the array substrate further comprises:
a protective layer, provided on a side of the conductive enhancement layer away from the first base substrate.

26-29. (canceled)

30. A display panel, comprising:
an array substrate, having a display region and a transition region provided on at least one side of the display region, wherein the array substrate comprises: a first base substrate; an insulating layer group, provided on a side of the first base substrate, wherein a recessed portion is provided on the insulating layer group, and the recessed portion is located in the transition region; a first electrode layer, provided on a side of the insulating layer group away from the first base substrate; and a conductive enhancement layer, provided on a side of the first electrode layer away from the first base substrate, wherein an orthographic projection of the conductive enhancement layer on the first base substrate is located within an orthographic projection of the first electrode layer on the first base substrate; and
a color film substrate, provided opposite to the array substrate, wherein the color film substrate comprises a black matrix, and an orthographic projection of the conductive enhancement layer on the first base substrate is located within an orthographic projection of the black matrix on the first base substrate.

31-32. (canceled)
